(19) United States
(12) Patent Application Publication
(10) Pub. No.: US 2025/0062128 A1
(43) Pub. Date: Feb. 20, 2025

(54) METHOD OF FORMING STRUCTURES FOR THRESHOLD VOLTAGE CONTROL

(71) Applicant: ASM IP Holding B.V., Almere (NL)

(72) Inventors: Maart van Druenen, Helsinki (FI); Charles Dezelah, Helsinki (FI); Qi Xie, Wilsele (BE); Petro Deminskyi, Helsinki (FI); Giuseppe Alessio Verni, Jodoigne (BE); Ren-Jie Chang, Leuven (BE); Lifu Chen, Helsinki (FI)

(21) Appl. No.: 18/922,849

(22) Filed: Oct. 22, 2024

Related U.S. Application Data
(63) Continuation of application No. 17/546,186, filed on Dec. 9, 2021, now Pat. No. 12,159,788.
(60) Provisional application No. 63/125,194, filed on Dec. 14, 2020.

(51) Int. Cl. H01L 21/28; C23C 16/32; H01L 29/40; H01L 29/49

(52) U.S. Cl. CPC H01L 21/28088; C23C 16/32; H01L 29/401; H01L 29/4966

(57) ABSTRACT

Methods and systems for depositing rare earth metal carbide containing layers on a surface of a substrate and structures and devices formed using the methods are disclosed. An exemplary method includes using a cyclical deposition process such as an atomic layer deposition process for depositing a rare earth metal carbide containing layer onto a surface of the substrate.

### CROSS-REFERENCE TO RELATED APPLICATIONS

This application is a continuation of, and claims priority to, U.S. patent application Ser. No. 17/546,186 filed Dec. 9, 2021 and titled METHOD OF FORMING STRUCTURES FOR THRESHOLD VOLTAGE CONTROL; the '186 Application claims priority to U.S. Provisional Patent Application Ser. No. 63/125,194 filed Dec. 14, 2020 and titled METHOD OF FORMING STRUCTURES FOR THRESHOLD VOLTAGE CONTROL, the disclosures of which are hereby incorporated by reference in their entirety.

### FIELD OF INVENTION

The present disclosure generally relates to methods and systems suitable for forming a layer on a surface of a substrate and to structures including the layer. More particularly, the disclosure relates to methods and systems for forming layers that allow controlling the threshold voltage of metal-oxide-semiconductor field-effect transistors (MOSFETs) and to structures formed using the methods and systems.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes. For example, one challenge has been finding suitable dielectric stacks that form an insulating barrier between a gate and a channel of a field effect transistor. One particular problem in this regard is controlling the threshold voltage of field effect transistors.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of forming structures including rare earth metal carbide containing layers, to structures and devices formed using such methods, and to apparatus for performing the methods and/or for forming the structures and/or devices. The rare earth metal carbide containing layers can be used in a variety of applications, including reducing power consumption in integrated circuits. The methods can comprise a cyclical deposition process. The cyclical deposition process can include one or more of an atomic layer deposition process and a cyclical chemical vapor deposition process. The cyclical deposition process can include a thermal process—i.e., a process that does not use plasma-activated species. In some cases, a reactant can be exposed to a plasma to form activated reactant species, e.g. radicals and/or ions.

Described herein is a method for depositing a rare earth metal carbide containing layer on a substrate. The method comprises providing a substrate within a reaction chamber. The substrate comprises a surface layer. The method further comprises depositing a rare earth metal carbide containing layer onto the surface layer by means of a cyclical deposition process. The cyclical deposition process comprises one or more cycles. A cycle comprises a precursor pulse and a reactant pulse. The precursor pulse comprises providing a rare earth metal precursor to the reaction chamber. The reactant pulse comprises providing a carbon reactant to the reaction chamber. Thus, a rare earth metal carbide containing layer is formed on the substrate.

Further described herein is a method for forming an electrode on a substrate. The method comprises providing a substrate within a reaction chamber. The substrate comprises a gate dielectric. The method further comprises depositing a first conductive layer on the gate dielectric, and subsequently depositing a rare earth metal carbide containing layer onto the first conductive layer by means of a cyclical deposition process. The cyclical deposition process comprises one or more cycles. A cycle comprises a precursor pulse and a reactant pulse. The precursor pulse comprises providing a rare earth metal precursor to the reaction chamber. The reactant pulse comprises providing a carbon reactant to the reaction chamber. Then, the method comprises depositing a second conductive layer on the rare earth metal carbide. Thus, an electrode is formed on the substrate. The electrode comprises the first conductive layer, the rare earth metal carbide containing layer, and the second conductive layer.

In some embodiments, the rare earth metal carbide containing layer comprises a rare earth metal carbide selected from lanthanum carbide, yttrium carbide, erbium carbide, samarium carbide, europium carbide, ytterbium carbide, and cerium carbide; and the rare earth metal precursor is selected from a lanthanum precursor, an yttrium precursor, an erbium precursor, a samarium precursor, an europium precursor, an ytterbium precursor, and a cerium precursor.

In some embodiments, the rare earth metal precursor comprises at least one of a rare earth metal in oxidation state +3 and a rare earth metal in oxidation state +4.

In some embodiments, the rare earth metal carbide layer comprises cerium carbide, and the rare earth metal precursor comprises a cerium precursor.

In some embodiments, the rare earth metal precursor comprises a substituted or unsubstituted cyclopentadienyl ligand.

In some embodiments, the rare earth metal precursor comprises a C1 to C4 alkyl-substituted cyclopentadienyl ligand.

In some embodiments, the alkyl-substituted cyclopentadienyl ligand is selected from EtCp, MeCp, iPrCp, nBuCp, and tBuCp.

In some embodiments, the rare earth metal precursor comprises an alkylsilyl-substituted cyclopentadienyl ligand.

In some embodiments, the cerium precursor is Ce(iPrCp)₃.

In some embodiments, the carbon reactant comprises a halogenated C1 to C6 alkane or alkene.

In some embodiments, the carbon reactant comprises iodine.

In some embodiments, the carbon reactant is selected from C₂H₅I, C₂H₄I₂, CH₂I₂, CHI₃, CH₃I, and CI₄.

In some embodiments, the carbon reactant comprises C₂H₄I₂.

In some embodiments, the first conductive layer comprises a first transition metal nitride.

In some embodiments, the first transition metal nitride comprises titanium nitride.

In some embodiments, the second conductive layer comprises a second transition metal nitride.

In some embodiments, the second transition metal nitride comprises titanium nitride.

In some embodiments, the first conductive layer comprises a first transition metal carbide.

In some embodiments, the first transition metal carbide comprises titanium carbide.

In some embodiments, the second conductive layer comprises a second transition metal carbide.

In some embodiments, the second transition metal carbide comprises titanium carbide.

In some embodiments, at least one of the first conductive layer and the second conductive layer comprises silicon nitride.

In some embodiments, at least one of the first conductive layer and the second conductive layer comprises a metal.

In some embodiments, the precursor pulse precedes the reactant pulse.

In some embodiments, the cyclical deposition process further comprises a first hydrogen pulse, and the first hydrogen pulse comprises providing a first hydrogen containing gas to the reaction chamber.

In some embodiments, the first hydrogen-containing gas comprises H₂.

In some embodiments, the first hydrogen pulse occurs after the precursor pulse and before the reactant pulse.

In some embodiments, the cyclical deposition process further comprises a second hydrogen pulse. The second hydrogen pulse comprises providing a second hydrogen containing gas to the reaction chamber, and the second hydrogen pulse occurs after the reactant pulse.

In some embodiments, the second hydrogen containing gas comprises H₂.

In some embodiments, the cyclical deposition process comprises a further precursor pulse. The further precursor pulse comprises providing a further precursor to the reaction chamber.

In some embodiments, the further precursor and the rare earth metal precursor are different.

In some embodiments, the further precursor comprises at least one of a rare earth metal and a transition metal.

In some embodiments, the further precursor pulse is followed by a third hydrogen pulse. The third hydrogen pulse comprises providing a third hydrogen containing gas to the reaction chamber.

In some embodiments, the third hydrogen containing gas comprises H₂.

In some embodiments, the rare earth metal carbide containing layer is grown at a growth rate of 0.1 nm per cycle or less.

In some embodiments, the rare earth metal carbide containing layer is deposited at a temperature of at least 350° C. to at most 500° C.

In some embodiments, the rare earth metal carbide containing layer is deposited at a pressure of at least 0.5 Torr to at most 5 Torr.

In some embodiments, the rare earth metal carbide containing layer has a thickness from at least 0.5 nm to at most 5.0 nm.

In some embodiments, the rare earth metal carbide containing layer is deposited in a cross-flow reactor.

In some embodiments, the rare earth metal carbide containing layer is deposited in a showerhead reactor.

In some embodiments, the rare earth metal carbide containing layer is deposited in a hot-wall reactor.

In some embodiments, the precursor is provided to the reaction chamber from a temperature-controlled precursor vessel.

In some embodiments, the temperature controlled precursor vessel is maintained at a temperature of at least 100° C. to at most 200° C.

In some embodiments, the precursor is provided to the reaction chamber by means of a carrier gas.

In some embodiments, the carrier gas is nitrogen or a noble gas.

In some embodiments, the cyclical deposition process comprises a thermal process.

Further described herein is a system. The system comprises one or more reaction chambers; a precursor gas source comprising a precursor; a reactant gas source comprising a reactant; an exhaust source; and, a controller. The controller is configured to control gas flow into at least one of the one or more reaction chambers to carry out a method as described herein.

Further described herein is an electrode. The electrode comprises a stack of layers, in the following order: a first conductive layer, a rare earth metal carbide containing layer, and a second conductive layer.

In some embodiments, the rare earth metal carbide containing layer comprises a rare earth metal carbide selected from lanthanum carbide, yttrium carbide, erbium carbide, and cerium carbide.

In some embodiments, rare earth metal carbide containing layer comprises cerium carbide.

In some embodiments, the first conductive layer comprises a first transition metal nitride.

In some embodiments, the first transition metal nitride comprises titanium nitride.

In some embodiments, the second conductive layer comprises a second transition metal nitride.

In some embodiments, the second transition metal nitride comprises titanium nitride.

In some embodiments, the first conductive layer has a thickness of at least 0.8 nm to at most 4.5 nm.

In some embodiments, the second conductive layer has a thickness of at least 1 nm to at most 20 nm.

In some embodiments, the rare earth metal carbide containing layer has a thickness of at least 0.07 nm to at most 5 nm.

Further described herein is an electrode as described herein, formed by means of a method as described herein.

Further described is a metal-oxide-semiconductor field effect transistor comprising a gate stack. The gate stack comprises an electrode as described herein.

In some embodiments, the metal-oxide-semiconductor field effect transistor has a gate-all-around architecture.

These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIG. 2 illustrates a method in accordance with exemplary embodiments of the disclosure.

FIG. 3 illustrates a method in accordance with exemplary embodiments of the disclosure.

FIG. 4 illustrates a structure (400) in accordance with exemplary embodiments of the disclosure.

FIG. 5 illustrates a structure (500) in accordance with exemplary embodiments of the disclosure.

FIG. 6 illustrates a structure (600) in accordance with exemplary embodiments of the disclosure.

FIG. 7 illustrates a system (700) in accordance with exemplary embodiments of the disclosure.

FIG. 8 shows transmission electron micrographs of exemplary cerium carbide containing layers deposited by means of an embodiment of a method according to this disclosure.

FIG. 9 shows capacitance voltage measurements on a test structure containing a cerium carbide containing layer deposited by means of an embodiment of a method according to this disclosure, compared to a reference.

FIG. 10 show test results obtained from capacitance voltage measurements on a test structure containing a cerium carbide containing layer deposited by means of an embodiment of a method according to this disclosure, compared to a reference.

FIG. 11 illustrates a method in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for forming structures, such as gate dielectrics or portions thereof for field effect transistors. Exemplary methods can be used to, for example, form CMOS devices, or portions of such devices. However, unless noted otherwise, the invention is not necessarily limited to such examples.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, particularly a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may or may not be continuous.

As used herein, the term “gate all around transistor” may refer to devices which include a conductive material wrapped around a semiconductor channel region. As used herein, the term “gate all around transistor” may also refer to a variety of device architectures such as nanosheet devices, forksheet devices, vertical field effect transistors, stacked device architectures, etc.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component. In preferred embodiments, a cyclic deposition process as disclosed herein refers to an atomic layer deposition process.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material) and forming material, e.g. about a monolayer or sub-monolayer of material, or several monolayers of material, or a plurality of monolayers of material, that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber. Note that, as used herein, ALD processes are not necessarily comprised of a sequence of self-limiting surface reactions.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In this disclosure, the following abbreviations are used: RE-M stands for rare earth metal, Cp stands for cyclopentadienyl, MeCp stands for methylcyclopentadienyl, EtCp stands for ethylcyclopentadienyl, iPrCp stands for isopropylcyclopentadienyl, nPrCp stands for n-propyl cyclopentadienyl, tBuCp stands for tert-butyl cyclopentadienyl, and TMSCp stands for trimethylsilylcyclopentadienyl. Me stands for methyl; Et stands for ethyl; iPr stands for isopropyl; nPr stands for n-propyl; nBu stands for n-butyl; acac stands for acetylacetonate; hfac stands for hexafluoroacetylacetonate; N^{R,R′} R″-amd″ or N^{R}R″-amd when R equals R′ refers to the amidinate ligand [R—N—C(R″)═N—R′], wherein R, R′ and R″ are C1-C5 hydrocarbyls, e.g. C1-C5 hydrocarbyls; R₂-fmd″ stands for an amidinate ligand in which R equals R′ and R″ equals H; R₂-amd″ stands for an amidinate ligand in which R equals R′, and R″ equals CH₃; thd stands for 2,2,6,6-tetramethylheptane-3,5-dionate; phen stands for phenanthroline.

The presently described methods and devices are useful for controlling the threshold voltage of field effect transistors. In some embodiments, the present methods and devices are particularly useful for controlling the threshold voltage of n-channel field effect transistors, such as n-channel metal-oxide semiconductor field effect transistors, such as n-channel gate-all-around metal oxide semiconductor field effect transistors. In some embodiments, the present methods and devices are particularly useful for controlling the threshold voltage of p-channel field effect transistors, such as p-channel metal-oxide semiconductor field effect transistors, such as p-channel gate-all-around metal oxide semiconductor field effect transistors. In some embodiments, the present methods and devices are particularly useful for inducing a negative flatband voltage shift for metal oxide semiconductor field effect transistors (MOSFETs). Thus, the present methods and devices may be particularly useful for decreasing the gate voltage at which a conductive channel is produced between the source and drain of an n-MOSFET. The n-MOSFET may, for example, be comprised in a CMOS-based integrated circuit. Additionally or alternatively, the present methods and devices may be particularly useful for increasing the gate voltage at which a conductive channel is produced between the source and drain of a p-MOSFET. The p-MOSFET may, for example, be comprised in a CMOS-based integrated circuit. In other words, the present methods and devices may be particularly useful for decreasing the voltage at which an n-MOSFET switches from an off-state to an on-state, and for increasing the voltage at which a p-MOSFET switches from an off-state to an on-state. Similarly, the present methods and devices may be particularly useful for decreasing the flat band voltage of n-MOSFETS, and for increasing the flat band voltage of p-MOSFETS. The presently methods and devices may be particularly useful for the manufacture of n-MOSFETS and p-MOSFETS with a gate-all-around architecture. Additionally or alternatively, the present methods and devices may be of particular use in the context of systems-on-a-chip.

In some embodiments, the present methods and devices are particularly useful for inducing a positive flatband voltage shift for metal oxide semiconductor field effect transistors (MOSFETs). Thus, the present methods and devices are particularly useful for increasing the gate voltage at which a conductive channel is produced between the source and drain of an n-MOSFET. The n-MOSFET may, for example, be comprised in a CMOS-based integrated circuit. Additionally or alternatively, the present methods and devices may be particularly useful for decreasing the gate voltage at which a conductive channel is produced between the source and drain of a p-MOSFET. The p-MOSFET may, for example, be comprised in a CMOS-based integrated circuit. In other words, the present methods and devices may be particularly useful for increasing the voltage at which an n-MOSFET switches from an off-state to an on-state, and for decreasing the voltage at which a p-MOSFET switches from an off-state to an on-state. Similarly, the present methods and devices may be particularly useful for increasing the flat band voltage of n-MOSFETS, and for decreasing the flat band voltage of p-MOSFETS. The presently described methods and devices may be particularly useful for the manufacture of n-MOSFETS and p-MOSFETS with a gate-all-around architecture. Additionally or alternatively, the present methods and devices may be of particular use in the context of systems-on-a-chip.

It shall be understood that when a metal nitride or carbide is abbreviated by means of a chemical formula, that chemical formula can indicate the metal nitride or carbide in the stoichiometry given, or in any other stoichiometry, including non-stoichiometric forms, depending, for example, on the oxidation state of the metal in question. For example, when titanium nitride is abbreviated as “TiN”, the term TiN can mean a titanium and nitrogen containing material in which titanium and nitrogen are present in a 1:1 ratio, or in any other suitable ratio, such as 0.8:1, 0.9:1, 0.95:1, 1:1.05, 1:1.1, 1.2, 1.5, etc.

Described herein are methods for depositing a rare earth metal carbide containing layer on a substrate. The methods comprise a step of providing a substrate in a reaction chamber. A suitable substrate includes a monocrystalline silicon wafer, e.g. a p-type monocrystalline silicon wafer. The substrate comprises a surface layer. The method further comprises a step of depositing a rare earth metal carbide containing layer onto the surface layer by means of a cyclical deposition process, such as an atomic layer deposition process or a cyclical chemical vapor deposition process. In some embodiments, the cyclical deposition process comprises one or more cycles. A cycle comprises two or more pulses. In some embodiments, at least one pulse involves a self-limiting surface reaction. In some embodiments, all pulses involve a self-limiting surface reaction. A cycle comprises a precursor pulse and a reactant pulse. In the precursor pulse, a rare earth metal precursor is provided to the reaction chamber, and in the reactant pulse, a carbon reactant is provided to the reaction chamber. Thus, a rare earth metal carbide containing layer is formed on the substrate.

In some embodiments, the presently described methods for depositing a rare earth metal carbide containing layer on a substrate can be used for forming a metal gate electrode for a CMOS, e.g. n-MOS or p-MOS, transistor. Thus, further described herein are methods for forming an electrode on a substrate. The methods comprises a step of providing a substrate in a reaction chamber. The substrate comprises a gate dielectric. Suitable gate dielectrics include high-k dielectrics such as hafnium oxide, zirconium oxide, aluminum oxide, and mixtures thereof. The methods further comprise depositing a first conductive layer on the gate dielectric. The method further comprises employing a cyclical deposition process to deposit a rare earth metal carbide containing layer onto the first conductive layer. The cyclical deposition process comprises one or more cycles. A cycle comprises providing a rare earth metal precursor to the reaction chamber in a precursor pulse. A cycle further comprises providing a carbon reactant to the reaction chamber in a reactant pulse. The methods then further comprise depositing a second conductive layer on the rare earth metal carbide layer. Thus, an electrode comprising the first conductive layer, the rare earth metal carbide containing layer, and the second conductive layer is formed on the substrate.

In some embodiments, the precursor pulse precedes the reactant pulse. This notwithstanding, and in other embodiments, the reactant pulse may precede the precursor pulse.

In some embodiments, the cyclical deposition process further comprises a first hydrogen pulse. The first hydrogen pulse comprises providing a first hydrogen containing gas to the reaction chamber. Suitably, the first hydrogen-containing gas can comprise H₂.

In some embodiments, the first hydrogen pulse occurs after the precursor pulse and before the reactant pulse. Advantageously, doing so allows controlling the rare earth metal and carbon content of the rare earth metal carbide containing layer. In other words, the first hydrogen pulse advantageously allows controlling the stoichiometry of the rare earth metal carbide containing layer. Without the presently disclosed subject matter being bound by any particular theory or mode of operation, it is believed that the first hydrogen pulse can result in a weakening and/or breaking of the chemical bond between the rare earth metal and the ligands in the rare earth metal precursor. Additionally alternatively, it is believed that the first hydrogen pulse can transform carbon- and hydrogen-containing ligands comprised in the rare earth metal precursor into volatile by-products such as CH₄, which are readily removed from the substrate surface and from the reaction chamber. Thus, the first hydrogen pulse advantageously allows for removal of residual carbon.

In some embodiments, the cyclical deposition process further comprises a second hydrogen pulse. The second hydrogen pulse comprises providing a second hydrogen containing gas, such as H₂, to the reaction chamber. It shall be understood that the second hydrogen pulse can occur after the reactant pulse. In other words, while the cyclical process is ongoing, the second hydrogen pulse can suitably occur after the reactant pulse, and before the precursor pulse.

In some embodiments, the cyclical deposition process comprises a first hydrogen pulse and a second hydrogen pulse. In such embodiments, the first hydrogen pulse occurs after the precursor pulse and before the reactant pulse, and the second hydrogen pulse occurs after the reactant pulse.

In some embodiments, the cyclical deposition process comprises a further precursor pulse. The further precursor pulse comprises providing a further precursor to the reaction chamber. Advantageously, the further precursor and the rare earth metal precursor are different. Thus, a rare earth carbide containing layer further comprising an additional element can be deposited. In some embodiments, the further precursor comprises at least one of a rare earth metal and a transition metal. Exemplary further precursors include transition metal precursors and rare earth metal precursors. For example, suitable transition metal precursors include iron precursors, titanium precursors, and vanadium precursors. Suitable rare earth metal precursors include lanthanum precursors, yttrium precursors, erbium precursors, samarium precursors, europium precursors, ytterbium precursors, gadolinium precursors, neodymium precursors and cerium precursors. In some embodiments, the further precursor comprises a substituted or unsubstituted cyclopentadienyl ligand. In some embodiments, the further precursor comprises a C1 to C4 alkyl-substituted cyclopentadienyl ligand. In some embodiments, the alkyl-substituted cyclopentadienyl ligand is selected from EtCp, MeCp, iPrCp, nPrCp, Cp, and tBuCp. In some embodiments, the further precursor includes an aluminum precursor.

In some embodiments, the further precursor pulse is followed by a third hydrogen pulse, wherein the third hydrogen pulse comprises providing a third hydrogen containing gas to the reaction chamber. In some embodiments, the third hydrogen containing gas comprises H₂.

It shall be understood that any two steps and/or pulses can be separated by a purge. Thus, in some embodiments, the step of depositing the first conductive layer and the step of depositing the rare earth metal carbide containing layer are separated by a purge. In some embodiments, the step of depositing the rare earth metal carbide containing layer and the step of depositing the second conductive layer are separated by a purge. In some embodiments, the precursor pulse and the reactant pulse are separated by a purge. In some embodiments, the reactant pulse and the further precursor pulse are separated by a purge. In some embodiments, the reactant pulse and the second hydrogen pulse are separated by a purge. In some embodiments, the second hydrogen pulse and the further precursor pulse are separated by a purge. In some embodiments, the further precursor pulse and the third hydrogen pulse are separated by a purge. In some embodiments, subsequent cycles are separated by a purge.

The rare earth metal carbide containing layer can comprise any rare earth metal carbide. In some embodiments, the rare earth metal carbide containing layer consists of a rare earth metal carbide. In some embodiments, the rare earth metal carbide containing layer comprises a rare earth metal carbide selected from lanthanum carbide, yttrium carbide, erbium carbide, samarium carbide, europium carbide, ytterbium carbide, gadolinium carbide, neodymium carbide, and cerium carbide; and the rare earth metal precursor is selected from a lanthanum precursor, an yttrium precursor, an erbium precursor, a samarium precursor, an europium precursor, an ytterbium precursor, and a cerium precursor.

The rare earth metal carbide containing layer can comprise a rare earth metal in any suitable oxidation state, e.g. in oxidation state +2, in oxidation state +3, or in oxidation state +4. In some embodiments, the rare earth metal precursor comprises a rare earth metal in oxidation state +3.

In some embodiments, the rare earth metal precursor comprises a substituted or unsubstituted cyclopentadienyl ligand. In some embodiments, the rare earth metal precursor comprises a C1 to C4 alkyl-substituted cyclopentadienyl ligand.

In some embodiments, the alkyl-substituted cyclopentadienyl ligand is selected from EtCp, MeCp, iPrCp, nBuCp, and tBuCp. When a rare earth metal contained in the rare earth metal precursor has an oxidation state of +3, then, in some embodiments, the rare earth metal precursor comprises a compound selected from RE-M(Cp)₃, RE-M(EtCp)₃, RE-M(MeCp)₃, RE-M(iPrCp)₃, RE-M(nPrCp)₃, RE-M(nBuCp)₃, and RE-M(tBuCp)₃. When a rare earth metal contained in the rare earth metal precursor has an oxidation state of +4, then, in some embodiments, the rare earth metal precursor comprises a compound selected from RE-M(Cp)₄, RE-M(EtCp)₄, RE-M(MeCp)₄, RE-M(iPrCp)₄, RE-M(nPrCp)₄, RE-M(nBuCp)₄, and RE-M(tBuCp)₄.

In some embodiments, the rare earth metal precursor comprises an alkylsilyl-substituted cyclopentadienyl ligand. In some embodiments, the alkylsilyl-substituted cyclopentadienyl ligand is selected from trimethylsilyl cyclopentadienyl, triethylsilyl cyclopentadienyl, and triisopropylsilyl cyclopentadienyl. When the rare earth metal contained in the rare earth metal precursor has an oxidation state of +3, then, in some embodiments, the rare earth metal precursor comprises RE-M(TMSCp)₃.

In some embodiments, the rare earth metal precursor comprises a rare earth metal diketonate. In some embodiments, the earth metal precursor is selected from the list consisting of: RE-M(acac)₄, RE-M(hfac)₃, RE-M(hfac)₄, RE-M(thd)₃, RE-M(thd)₄, and RE-M(thd)₃phen.

In some embodiments, the rare earth metal precursor comprises an amidinate ligand. In some embodiments, the rare earth metal precursor comprises a formamidinate (fmd) ligand. In some embodiments, the rare earth metal precursor comprises an acetamidinate (amd) ligand. In some embodiments, the rare earth metal precursor comprises an amidinate ligand selected from R₂-amd and R₂-fmd, wherein R is a linear or branched C1 to C4 alkyl. In some embodiments, the rare earth metal precursor comprises a compound of the form RE-M(R¹₂-amd)₃, RE-M(R¹₂-fmd)₃, RE-M(R²₂Cp)₂(R¹₂-amd), and RE-M(R²₂Cp)₂(R¹₂-fmd), RE-M(R¹₂-amd)₄, RE-M(R¹₂-fmd)₄, RE-M(R²₂Cp)₃(R¹₂-amd), RE-M(R²₂Cp)₂(R¹₂-amd)₂, RE-M(R²₂Cp)(R¹₂-amd)₃, RE-M(R²₂Cp)₃(R¹₂-fmd), RE-M(R²₂Cp)₂(R¹₂-fmd)₂, and RE-M(R²₂Cp)(R¹₂-fmd)₃, wherein R¹ and R² are independently selected from a linear or branched C1 to C4 alkyl. In some embodiments, the rare earth metal precursor comprises at least one of RE-M(iPr₂-amd)₃, RE-M(tBu₂-amd)₃, and RE-M(iPrCp)₂(iPr₂-amd), RE-M(Cp)₂(iPr₂-amd), RE-M(MeCp)₂(iPr₂-amd), RE-M(EtCp)₂(iPr₂-amd), RE-M(nPrCp)₂(iPr₂-amd), RE-M(tBuCp)₂(iPr₂-amd), RE-M(iPr₂-amd)₄, RE-M(tBu₂-amd)₄, RE-M(iPrCp)₃(iPr₂-amd), RE-M(iPrCp)₂(iPr₂-amd)₂, RE-M(iPrCp) (iPr₂-amd)₃, RE-M(Cp)₃(iPr₂-amd), RE-M(Cp)₂(iPr₂-amd)₂, RE-M(Cp) (iPr₂-amd)₃, RE-M(MeCp)₃(iPr₂-amd), RE-M(MECp)₂(iPr₂-amd)₂, RE-M(MeCp) (iPr₂-amd)₃, RE-M(EtCp)₃(iPr₂-amd), RE-M(EtCp)₂(iPr₂-amd)₂, RE-M(EtCp) (iPr₂-amd)₃, RE-M(nPrCp)₃(iPr₂-amd), RE-M(nPrCp)₂(iPr₂-amd)₂, RE-M(nPrCp) (iPr₂-amd)₃, RE-M(tBuCp)₃(iPr₂-amd), RE-M(tBuCp)₂(iPr₂-amd)₂, RE-M(tBuCp) (iPr₂-amd)₃. In some embodiments, the rare earth metal precursor comprises at least one of RE-M(iPr₂-fmd)₃, RE-M(tBu₂-fmd)₃, and RE-M(iPrCp)₂(iPr₂-fmd), RE-M(Cp)₂(iPr₂-fmd), RE-M(MeCp)₂(iPr₂-fmd), RE-M(EtCp)₂(iPr₂-fmd), RE-M(nPrCp)₂(iPr₂-fmd), RE-M(tBuCp)₂(iPr₂-fmd), RE-M(iPr₂-fmd)₄, RE-M(tBu₂-fmd)₄, RE-M(iPrCp)₃(iPr₂-fmd), RE-M(iPrCp)₂(iPr₂-fmd)₂, RE-M(iPrCp) (iPr₂-fmd)₃, RE-M(Cp)₃(iPr₂-fmd), RE-M(Cp)₂(iPr₂-fmd)₂, RE-M(Cp)(iPr₂-fmd)₃, RE-M(MeCp)₃(iPr₂-fmd), RE-M(MECp)₂(iPr₂-fmd)₂, RE-M(MeCp)(iPr₂-fmd)₃, RE-M(EtCp)₃(iPr₂-fmd), RE-M(EtCp)₂(iPr₂-fmd)₂, RE-M(EtCp) (iPr₂-fmd)₃, RE-M(nPrCp)₃(iPr₂-fmd), RE-M(nPrCp)₂(iPr₂-fmd)₂, RE-M(nPrCp)(iPr₂-fmd)₃, RE-M(tBuCp)₃(iPr₂-fmd), RE-M(tBuCp)₂(iPr₂-fmd)₂, and RE-M(tBuCp) (iPr₂-fmd)₃.

In some embodiments, the rare earth metal precursor comprises a rare earth metal alkoxide such as RE-M(OCMe₂CH₂OMe)₄.

In some embodiments, the rare earth metal precursor comprises one or more rare earth metal alkylsylilamines. An exemplary earth metal alkylsilylamine includes Ce[N(SiMe₃)₂]₃.

In some embodiments, the rare earth metal carbide layer comprises cerium carbide, and the rare earth metal precursor comprises a cerium precursor. The inventors surprisingly found that cerium carbide containing layers can be particularly advantageous for increasing the threshold voltage of p-channel metal oxide semiconductor field effect transistors. Also, the inventors surprisingly found that cerium carbide containing layers can be particularly advantageous for decreasing the threshold voltage of n-channel metal oxide semiconductor field effect transistors.

Exemplary cerium precursors comprise cerium diketonates, cerium amidinates, cerium cyclopentadienyls, cerium alkoxides, and cerium alkylsilylamines.

In some embodiments, the cerium precursor comprises a substituted or unsubstituted cyclopentadienyl ligand. In some embodiments, the cerium precursor comprises a C1 to C4 alkyl-substituted cyclopentadienyl ligand.

In some embodiments, the alkyl-substituted cyclopentadienyl ligand is selected from EtCp, MeCp, iPrCp, Cp, nBuCp, and tBuCp. In some embodiments, the cerium precursor comprises a compound selected from Ce(Cp)₃, Ce(EtCp)₃, Ce(MeCp)₃, Ce(iPrCp)₃, Ce(nPrCp)₃, Ce(nBuCp)₃, and Ce(tBuCp)₃. In some embodiments, the cerium precursor comprises Ce(iPrCp)₃. In some embodiments, the cerium precursor comprises a compound selected from Ce(Cp)₄, Ce(EtCp)₄, Ce(MeCp)₄, Ce(iPrCp)₄, Ce(nPrCp)₄, Ce(nBuCp)₄, and Ce(tBuCp)₄. In some embodiments, the cerium precursor comprises Ce(iPrCp)₄.

In some embodiments, the cerium precursor comprises an alkylsilyl-substituted cyclopentadienyl ligand. In some embodiments, the alkylsilyl-substituted cyclopentadienyl ligand is selected from trimethylsilyl cyclopentadienyl, triethylsilyl cyclopentadienyl, and triisopropylsilyl cyclopentadienyl. In some embodiments, the cerium precursor comprises Ce(TMSCp)₃.

In some embodiments, the cerium precursor comprises a cerium diketonate. In some embodiments, the cerium precursor is selected from the list consisting of: Ce(acac)₄, Ce(hfac)₄, Ce(thd)₄, and Ce(thd)₃phen.

In some embodiments, the cerium precursor comprises an amidinate ligand. In some embodiments, the cerium precursor comprises a formamidinate ligand. In some embodiments, the cerium precursor comprises an acetamidinate ligand. In some embodiments, the cerium comprises an amidinate ligand selected from R₂-amd and R₂-fmd, wherein R is a linear or branched C1 to C4 alkyl. In some embodiments, the cerium precursor comprises a compound selected from the list Ce(R¹₂-amd)₃, Ce(R¹₂-fmd)₃, Ce(R²₂Cp)₂(R¹₂-amd), Ce(R²₂Cp)₂(R¹₂-fmd), Ce(R¹₂-amd)₄, Ce(R¹₂-fmd)₄, Ce(R²₂Cp)₃(R¹₂-amd), Ce(R²₂Cp)₂(R¹₂-amd)₂, Ce(R²₂Cp)(R¹₂-amd)₃, Ce(R²₂Cp)₃(R₂-fmd), Ce(R²₂Cp)₂(R¹₂-fmd)₂, and Ce(R²₂Cp)(R¹₂-fmd)₃, wherein R¹ and R² are independently selected from a linear or branched C1 to C4 alkyl. In some embodiments, the cerium precursor comprises at least one of Ce(iPr₂-amd)₃, Ce(tBu₂-amd)₃, and Ce(iPrCp)₂(iPr₂-amd), Ce(Cp)₂(iPr₂-amd), Ce(MeCp)₂(iPr₂-amd), Ce(EtCp)₂(iPr₂-amd), Ce(nPrCp)₂(iPr₂-amd), Ce(tBuCp)₂(iPr₂-amd), Ce(iPr₂-amd)₄, Ce(tBu₂-amd)₄, Ce(iPrCp)₃(iPr₂-amd), Ce(iPrCp)₂(iPr₂-amd)₂, Ce(iPrCp) (iPr₂-amd)₃, Ce(Cp)₃(iPr₂-amd), Ce(Cp)₂(iPr₂-amd)₂, Ce(Cp)(iPr₂-amd)₃, Ce(MeCp)₃(iPr₂-amd), Ce(MECp)₂(iPr₂-amd)₂, Ce(MeCp) (iPr₂-amd)₃, Ce(EtCp)₃(iPr₂-amd), Ce(EtCp)₂(iPr₂-amd)₂, Ce(EtCp) (iPr₂-amd)₃, Ce(nPrCp)₃(iPr₂-amd), Ce(nPrCp)₂(iPr₂-amd)₂, Ce(nPrCp) (iPr₂-amd)₃, Ce(tBuCp)₃(iPr₂-amd), Ce(tBuCp)₂(iPr₂-amd)₂, and Ce(tBuCp) (iPr₂-amd)₃. In some embodiments, the cerium precursor comprises at least one of Ce(iPr₂-fmd)₃, Ce(tBu₂-fmd)₃, and Ce(iPrCp)₂(iPr₂-fmd), Ce(Cp)₂(iPr₂-fmd), Ce(MeCp)₂(iPr₂-fmd), Ce(EtCp)₂(iPr₂-fmd), Ce(nPrCp)₂(iPr₂-fmd), Ce(tBuCp)₂(iPr₂-fmd), Ce(iPr₂-fmd)₄, Ce(tBu₂-fmd)₄, Ce(iPrCp)₃(iPr₂-fmd), Ce(iPrCp)₂(iPr₂-fmd)₂, Ce(iPrCp) (iPr₂-fmd)₃, Ce(Cp)₃(iPr₂-fmd), Ce(Cp)₂(iPr₂-fmd)₂, Ce(Cp)(iPr₂-fmd)₃, Ce(MeCp)₃(iPr₂-fmd), Ce(MECp)₂(iPr₂-fmd)₂, Ce(MeCp)(iPr₂-fmd)₃, Ce(EtCp)₃(iPr₂-fmd), Ce(EtCp)₂(iPr₂-fmd)₂, Ce(EtCp)(iPr₂-fmd)₃, Ce(nPrCp)₃(iPr₂-fmd), Ce(nPrCp)₂(iPr₂-fmd)₂, Ce(nPrCp)(iPr₂-fmd)₃, Ce(tBuCp)₃(iPr₂-fmd), Ce(tBuCp)₂(iPr₂-fmd)₂, and Ce(tBuCp) (iPr₂-fmd)₃.

In some embodiments, the cerium precursor comprises a cyclopentadienyl ligand. In other words, and in some embodiments, the cerium precursor comprises a cerium cyclopentadienyl. In some embodiments, the cerium precursor comprises a compound selected from the list consisting of Ce(Cp)₃, Ce(EtCp)₃, Ce(MeCp)₃, Ce(nPrCp)₃, Ce(tBuCp)₃, Ce(nBuCp)₃, and Ce(iPrCp)₃. In some embodiments, the cerium precursor comprises a compound selected from the list consisting of Ce(Cp)₄, Ce(EtCp)₄, Ce(MeCp)₄, Ce(nPrCp)₄, Ce(tBuCp)₄, Ce(nBuCp)₄, and Ce(iPrCp)₄.

In some embodiments, the cerium precursor comprises a cerium alkoxide such as Ce(OCMe₂CH₂OMe)₄.

In some embodiments, the cerium precursor comprises one or more cerium alkylsylilamines. An exemplary cerium alkylsilylamine includes Ce[N(SiMe₃)₂]₃.

In some embodiments, the rare earth metal carbide layer comprises yttrium carbide, and the rare earth metal precursor comprises an yttrium precursor. In some embodiments, the yttrium precursor comprises a cyclopentadienyl ligand and/or or an alkyl-substituted cyclopentadienyl ligand such as EtCp. In some embodiments, the yttrium precursor comprises an amidinate ligand, e.g. an alkylamidinate ligand such as iPr-amd. An exemplary yttrium precursor includes Y(EtCp)₂(iPr-amd).

In some embodiments, the rare earth metal carbide layer comprises lanthanum carbide, and the rare earth metal precursor comprises a lanthanum precursor. In some embodiments, the rare earth metal carbide containing layer comprises lanthanum, and the precursor comprises a lanthanum precursor.

In some embodiments, the lanthanum precursor comprises one or more cyclopentadienyl ligands or alkyl substituted variants thereof.

In some embodiments, the lanthanum precursor comprises a lanthanum amidinate.

In some embodiments, the lanthanum precursor is selected from the list consisting of La(iPrCp)₃, La(Cp)₃, La(EtCp)₃, La(MeCp)₃, La(nPrCp)₃, La(tBuCp)₃, and La(nBuCp)₃.

In some embodiments, the lanthanum precursor comprises one or more substituted or unsubstituted cyclopentadienyl ligands. Additionally or alternatively, the lanthanum precursor comprises one or more ligands selected from an alkylsilylamine, a diazadiene, and an amidinate.

In some embodiments, the carbon reactant comprises a halogenated C1 to C6 alkane or alkene. Thus, in some embodiments, the carbon reactant comprises C, H, and a halogen. Suitable halogens include, F, Cl, Br, and I. In some embodiments, the carbon reactant comprises iodine. Suitable iodine-containing carbon reactants include C₂H₅I, C₂H₄I₂, CH₂I₂, CHI₃, CH₃I, and CI₄. 14. In some embodiments, the carbon reactant comprises C₂H₄I₂.

In some embodiments, the first conductive layer comprises a first transition metal nitride. Suitable transition metal nitrides for use as a first transition metal nitride include TiN, ZrN, HfN, VN, Mo, NbN, TaN, ScN, CrN, MoN, and WN.

In some embodiments, the second conductive layer comprises a second transition metal nitride, which is different from the first transition metal nitride. Suitable transition metal nitrides for use as a second transition metal nitride include TiN, ZrN, HfN, VN, Mo, NbN, TaN, ScN, CrN, MoN, and WN.

In some embodiments, the first conductive layer comprises a first transition metal carbide. Suitable transition metal carbides for use as a first transition metal carbide include TiC, VC, HfC, TaC, ZrC, ScC, NbC.

In some embodiments, the second conductive layer further comprises a second transition metal carbide, which is different than the first transition metal carbide. Suitable transition metal carbides for use as a second transition metal carbide include TiC, VC, HfC, TaC, ZrC, ScC, and NbC.

In some embodiments, the second conductive layer comprises aluminum carbide. In some embodiments, the second conductive layer comprises titanium carbide and aluminum carbide.

In some embodiments, at least one of the first conductive layer and the second conductive layer comprises silicon nitride. In some embodiments, the first conductive layer comprises silicon nitride. In some embodiments, the second conductive layer comprises silicon nitride.

In some embodiments, at least one of the first conductive layer and the second conductive layer comprises a metal. In some embodiments, the first conductive layer comprises a metal. In some embodiments, the second conductive layer comprises a metal. Suitable metals include Cu, Co, Al, V, Cr, Y, Re, Ru, Mo, W, and Ti.

It shall be understood that when a rare earth metal carbide containing layer is deposited on the first conductive layer, and/or when the second conductive layer is deposited on the rare earth metal carbide containing layer, intermixing of those layer's constituent components may occur to some extent. For example, when a cerium carbide containing layer is deposited on a titanium nitride layer, at least one of titanium and nitrogen may be incorporated in the cerium carbide containing layer, for example by means of diffusion, surface segregation, or another process. In some embodiments, such intermixing can result in the formation of an interlayer containing both components of the conductive layer and the rare earth metal carbide containing layer. For example, such an interlayer can comprise cerium carbonitride when a cerium carbide containing layer is deposited on a titanium nitride layer. In some embodiments, intermixing can result in alloying or doping of the rare earth metal carbide containing layer. For example, when the rare earth metal carbide containing layer is deposited on a transmission metal nitride, the rare earth metal carbide containing layer may be doped with nitrogen.

It shall be understood that the following embodiments can apply to any one of the methods disclosed herein, irrespective of the precursor and/or reactant that is used in such methods, unless a corresponding embodiment would render the method in question unworkable.

In some embodiments, the rare earth metal carbide containing layer is grown at a growth rate of 0.1 nm per cycle or less.

In some embodiments, the rare earth metal carbide containing layer is deposited at a temperature of at least 100° C. to at most 500° C., or at a temperature of at least 200° C. to at most 450° C., or at a temperature of at least 300° C. to at most 400° C., or at a temperature of at least 350° C. to at most 450° C.

In some embodiments, the precursor is provided to the reaction chamber from a precursor source maintained at a temperature of at least 25° C. to at most 200° C., or at a temperature of at least 50° C. to at most 150° C., or at a temperature of at least 75° C. to at most 125° C.

In some embodiments, the reactant is provided to the reaction chamber from a reactant source maintained at a temperature of at least 25° C. to at most 200° C., or at a temperature of at least 50° C. to at most 150° C., or at a temperature of at least 75° C. to at most 125° C.

In some embodiments, the rare earth metal carbide containing layer is deposited at a pressure of at least 0.01 Torr to at most 100 Torr, or at a pressure of at least 0.1 Torr to at most 50 Torr, or at a pressure of at least 0.5 Torr to at most 25 Torr, or at a pressure of at least 1 Torr to at most 10 Torr, or at a pressure of at least 2 Torr to at most 5 Torr.

In some embodiments, the rare earth metal carbide containing layer has a thickness from at least 0.3 nm to at most 5.0 nm.

The rare earth metal carbide containing layer can be deposited in any suitable reactor. Thus, in some embodiments, the rare earth metal carbide containing layer is deposited in a cross-flow reactor. In some embodiments, the rare earth metal carbide containing layer is deposited in a showerhead reactor. In some embodiments, the rare earth metal carbide containing layer is deposited in a hot-wall reactor. Doing so can advantageously enhance uniformity and/or repeatability of rare earth metal carbide containing layer deposition processes.

In some embodiments, the substrate is subjected to an annealing step in an ambient comprising hydrogen and nitrogen after the cyclical deposition process. Suitably, the annealing step can be carried out at a temperature from at least 300° C. to at most 600° C. Alternatively, the annealing step can be carried out at a temperature from at least 300° C. to at most 1000° C.

In some embodiments, the precursor is provided to the reaction chamber from a temperature-controlled precursor vessel. In some embodiments, the temperature-controlled precursor vessel is configured for cooling the precursor. In some embodiments, the temperature-controlled precursor vessel is configured for heating the precursor. In some embodiments, the temperature controlled precursor vessel is maintained at a temperature of at least −50° C. to at most 20° C., or at a temperature of at least 20° C. to at most 250° C., or at a temperature of at least 100° C. to at most 200° C.

In some embodiments, the precursor is provided to the reaction chamber by means of a carrier gas. Exemplary carrier gasses include nitrogen and a noble gas such as He, Ne, Ar, Xe, or Kr.

In some embodiments, the precursor pulses last from at least 0.01 s to at most 120 s, or from at least 0.01 s to at most 0.1 s, or from at least 0.01 s to at most 0.02 s, or from at least 0.02 s to at most 0.05 s, or from at least 0.05 s to at most 0.1 s, or from at least 0.1 s to at most 20 s, or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s. In some embodiments, the reactant pulses last from at least 0.1 s to at most 20 s or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s, or from at least 20.0 s to at most 120.0 s, or from at least 20.0 s to at most 50.0 s, or from at least 50.0 s to at most 80.0 s, or from at least 80.0 s to at most 120.0 s.

Advantageously, a cyclical deposition process as disclosed herein can be a thermal deposition process. In other words, in some embodiments, none of the pulses or purges in the cyclical deposition process employs a plasma. In the case of thermal cyclical deposition processes, a duration of the steps of providing the precursor to the reaction chamber, a duration of the step of providing the reactant to the reaction chamber, a duration of the step of providing the further precursor to the reaction chamber, and/or a duration of a step of providing a hydrogen containing gas to the reaction chamber can be relatively long to allow the precursor, reactant, further precursor, and/or hydrogen containing gas to react with a surface of the substrate. For example, the duration can be greater than or equal to 5 seconds or greater than or equal to 10 seconds or between about 5 and 10 seconds.

In some embodiments, the cyclical deposition process employs a plasma-enhanced deposition technology. For example, the cyclical deposition process may comprise a plasma-enhanced atomic layer deposition process and/or a plasma-enhanced chemical vapor deposition process. In such a case, any one of the pulses in the cyclical depositing process may comprise generating a plasma in the reaction chamber.

Further described herein is a system comprising: one or more reaction chambers; a precursor gas source comprising a precursor; a reactant gas source comprising a reactant; an exhaust source; and a controller. The controller is configured to control gas flow into at least one of the one or more reaction chambers to carry out a method as described herein.

Further described herein is an electrode. The electrode comprises a stack of layers, in the following order: a first conductive layer, a rare earth metal carbide containing layer, and a second conductive layer. Suitably, the rare earth metal carbide containing layer can comprise a rare earth metal carbide selected from lanthanum carbide, yttrium carbide, erbium carbide, gadolinium carbide, neodymium carbide, and cerium carbide. In some embodiments, the rare earth metal carbide containing layer comprises cerium carbide. Suitably, the electrode can be manufactured by means of a method as described herein.

In some embodiments, the first conductive layer comprises a first transition metal nitride such as TiN, MoN, VN, HfN, TaN, ZrN, ScN, or NbN.

In some embodiments, the second conductive layer comprises a second transition metal nitride such as TiN, MoN, VN, HfN, TaN, ZrN, ScN, or NbN. In some embodiments, the first layer and the second layer have an identical composition. In some embodiments, the first layer and the second layer have a different composition.

The first conductive layer, rare earth metal carbide containing layer, and the second conductive layer can have any suitable thickness, though typically the thickness of these layers is less than 50 nm. In some embodiments, the first conductive layer has a thickness of at least 0.3 nm to at most 3 nm, or of at least 0.5 nm to at most 2 nm, or of at least 1 nm to at most 2 nm. In some embodiments, the second conductive layer has a thickness of at least 0.3 nm to at most 50 nm, or of at least 0.5 nm to at most 30 nm, or of at least 1 nm to at most 20 nm, or of at least 5 nm to at most 10 nm. In some embodiments, the rare earth metal carbide containing layer has a thickness of at least 0.3 nm to at most 10 nm, or of at least 1 nm to at most 5 nm.

Further described herein is a metal-oxide-semiconductor field effect transistor comprising a gate stack that comprises an electrode as described herein. In some embodiments, the metal-oxide-semiconductor field effect transistor is a p-channel metal-oxide-semiconductor field effect transistor. In other embodiments, the metal-oxide-semiconductor field effect transistor is an n-channel metal-oxide-semiconductor field effect transistor. Suitably, the electrode completely surrounds the channel region of the metal-oxide-semiconductor field effect transistor, as is the case with metal-oxide-semiconductor field effect transistors having a gate-all-around architecture.

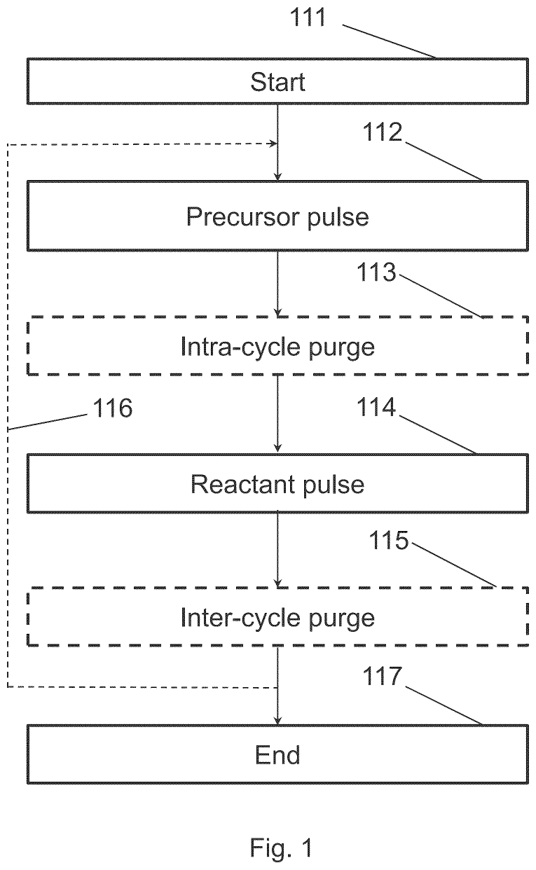

Turning now to the figures, FIG. 1 illustrates a method in accordance with exemplary embodiments of the disclosure. This method can be used, for example, for depositing a rare earth metal carbide containing layer for use in a gate electrode which is suitable for NMOS, and/or CMOS devices. The present layers are particularly suitable for use as threshold voltage control layers in p- or n-channel MOSFETs. However, unless otherwise noted, methods are not limited to such applications. The method starts (111) after a substrate has been provided to a reaction chamber, and involves depositing a rare earth metal carbide containing layer on the substrate by means of a cyclical deposition process that can be repeated (116) one or more times. The reaction chamber can be or include a reaction chamber of a chemical vapor deposition reactor system configured to perform a cyclical deposition process. Additionally or alternatively, the reaction chamber can be or can include a reaction chamber of an atomic layer deposition reactor system configured to perform a cyclical deposition process. The reaction chamber can be a standalone reaction chamber or part of a cluster tool. The cyclical deposition process comprises providing a rare earth metal carbide containing layer to the reaction chamber in a precursor pulse (112). In some embodiments, the method comprises a plurality of cycles, e.g. 2, 5, 10, or 20, or more cycles. Optionally, the reaction chamber is purged (113) after the precursor pulse (112). Then, a carbon reactant is provided to the reaction chamber in a reactant pulse (114). Optionally, the reaction chamber can be purged (115) after the reactant pulse. The precursor pulse (112), the reactant pulse (114), and the optional purges (113,115) can be repeated (116) any number of times to obtain a rare earth metal carbide containing layer having a desired thickness. When a rare earth metal carbide containing layer having a desired thickness has been deposited, the method ends (117). Once the method has ended, the substrate can, for example, be subjected to additional processes to form a device structure and/or device.

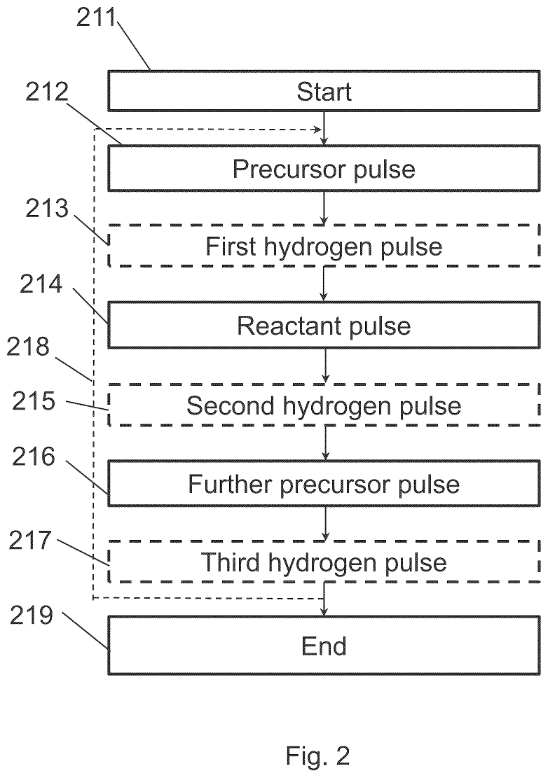

FIG. 2 illustrates another method in accordance with exemplary embodiments of the disclosure. Like the method of FIG. 1, the method of FIG. 2 can be used to, for example, form a rare earth metal carbide containing layer in a gate electrode structure for a metal oxide semiconductor field effect transistor. The method starts (211) after a substrate has been provided to a reaction chamber, and involves depositing a rare earth metal carbide containing layer on the substrate by means of a cyclical deposition process that can be repeated (218) one or more times. In some embodiments, the method comprises a plurality of cycles, e.g. 2, 5, 10, or 20, or more cycles. The reaction chamber can be or include a reaction chamber of a chemical vapor deposition reactor system configured to perform a cyclical deposition process. Additionally or alternatively, the reaction chamber can be or can include a reaction chamber of an atomic layer deposition reactor system configured to perform a cyclical deposition process. The reaction chamber can be a standalone reaction chamber or part of a cluster tool. The cyclical deposition process comprises providing a rare earth metal carbide containing layer to the reaction chamber in a precursor pulse (212). Optionally, a first hydrogen-containing gas is then provided to the reaction chamber in a first hydrogen pulse (213). Then, a carbon reactant is provided to the reaction chamber in a reactant pulse (214). Optionally, a second hydrogen-containing gas is then provided to the reaction chamber in a second hydrogen pulse (215). A further precursor is then provided to the reaction chamber in a further precursor pulse (216). After the further precursor pulse (216), a third hydrogen containing gas is then optionally provided to the reaction chamber in a third hydrogen pulse (217). The cyclical deposition process can be repeated (218) one or more times until the rare earth metal carbide containing layer has reached a desired thickness, whereafter the method ends (219). Once the method has ended, the substrate can, for example, be subjected to additional processes to form a device structure and/or device.

Optionally, any of the aforementioned pulses can be separated by a purge. Accordingly, in some embodiments, the precursor pulse (212) and the first hydrogen pulse (213) are separated by a purge. In some embodiments, the precursor pulse (212) and the reactant pulse (214) are separated by a purge. In some embodiments, the first hydrogen pulse (213) and the reactant pulse (214) are separated by a purge. In some embodiments, the reactant pulse (214) and the second hydrogen pulse (215) are separated by a purge. In some embodiments, the reactant pulse (214) and the further precursor pulse (216) are separated by a purge. In some embodiments, the second hydrogen pulse (215) and the further precursor pulse (216) are separated by a purge. In some embodiments, the further precursor pulse (216) and the third hydrogen pulse (217) are separated by a purge. In some embodiments, the third hydrogen pulse (217) is followed by a purge.

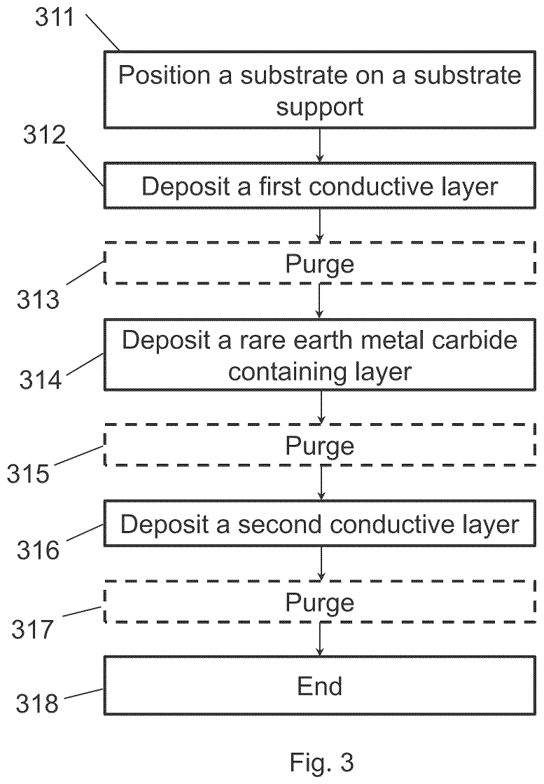

FIG. 3 illustrates another method in accordance with exemplary embodiments of the disclosure. This method can be used to, for example, form a gate electrode structure for a metal oxide semiconductor field effect transistor. The method of FIG. 3 comprises positioning a substrate on a substrate support comprised in a reaction chamber (311). The method further comprises depositing a first conductive layer (312). Optionally, the method then comprises purging the reaction chamber (313). Then, the method comprises depositing a rare earth metal carbide containing layer on the first conductive layer (314). Optionally, the method then comprises purging the reaction chamber (315). Then, the method comprises depositing a second conductive layer on the rare earth metal carbide containing layer (316). Optionally, the method then comprises purging the reaction chamber (317). Then, the method ends (318). Once the method has ended, the substrate can, for example, be subjected to additional processes to form a device structure and/or device. Note the first and the second conductive layers can comprise any conductive material, such as a metal or a nitride or a carbide, for example a transition metal nitride such as TiN, a transition metal such as Ti, or a transition metal carbide such as TiC. Optionally, the process according to FIG. 3 can be followed by a thermal treatment step, such as a forming gas anneal or a rapid thermal anneal.

It shall be understood that in a method according to FIG. 3, the rare earth metal carbide containing layer can be deposited using a cyclical deposition process as disclosed herein. The cyclical deposition process can include cyclical CVD, ALD, or a hybrid cyclical CVD/ALD process. Preferably, the cyclical deposition process employs reaction conditions which, when combined with a selected precursor-reactant pair, allow for self-limiting surface reactions to occur. For example, in some embodiments, the growth rate of a particular ALD process may be low compared with a CVD process.

Any one of the methods according to FIG. 1, 2, or 3 can include heating the substrate to a desired deposition temperature within the reaction chamber. In some embodiments of the disclosure, the method includes heating the substrate to a temperature of less than 500° C. For example, in some embodiments of the disclosure, heating the substrate to a deposition temperature may comprise heating the substrate to a temperature of at least 100° C. to at most 400° C., or at a temperature of at least 150° C. to at most 350° C., or at a temperature of at least 200° C. to at most 300° C. In addition to controlling the temperature of the substrate, a pressure within the reaction chamber may also be regulated. For example, in some embodiments of the disclosure, the pressure within the reaction chamber during the cyclical deposition process may be less than 760 Torr or between 0.2 Torr and 760 Torr, about 1 Torr and 100 Torr, or about 1 Torr and 10 Torr.

Any one of the methods according to FIG. 1, 2, or 3 may comprise one or more purges. During a purge, the reaction chamber can be purged using a vacuum and/or an inert gas to mitigate gas phase reactions between precursors and reactants and enable partly or fully self-saturating surface reactions—e.g., in the case of ALD. Additionally or alternatively, the substrate may be moved to separately contact a first vapor phase reactant, e.g. a precursor, and a second vapor phase reactant, e.g. a reactant. Additionally or alternatively, gaseous species may be removed from the reaction chamber during any one of the purges by mean of a gas removal device such as a pump. Surplus chemicals and reaction byproducts, if any, can be removed from the substrate surface or reaction chamber, such as by purging the reaction space or by moving the substrate, before the substrate is contacted with the next reactive chemical.

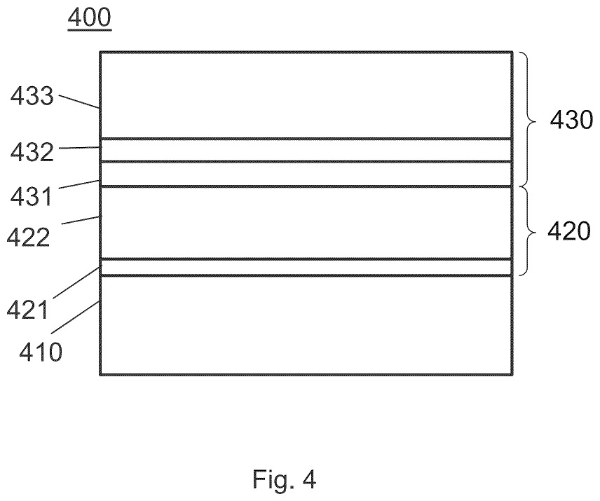

FIG. 4 illustrates a structure/a portion of a device (400) in accordance with additional examples of the disclosure. The device or structure (400) includes a substrate (410), dielectric or insulating material, i.e. a gate dielectric (420), and a gate electrode (430). The substrate (400) can be or include any of the substrate material described herein. The gate dielectric (420) can include one or more dielectric or insulating material layers. By way of example, the gate dielectric (420) can include an interfacial layer (421) and a high-k material (422) deposited overlying the interfacial layer (421). In some cases, the interfacial layer (421) may not exist or may not exist to an appreciable extent. The interfacial layer (421) can include an oxide, such as a silicon oxide, which can for example be formed on a, for example monocrystalline silicon, surface of the substrate (410) using, for example, a chemical oxidation process or an oxide deposition process. The high-k material (422) can be or include, for example, a metal oxide having a dielectric constant greater than about 7. In some embodiments, the high-k material has a dielectric constant higher than the dielectric constant of silicon oxide. Exemplary high-k materials include hafnium oxide (HfO₂), tantalum oxifde (Ta₂O₅), zirconium oxide (ZrO₂), titanium oxide (TiO₂), hafnium silicate (HfSiOₓ), aluminum oxide (Al₂O₃) or lanthanum oxide (La₂O₃), mixtures thereof, and laminates thereof. The gate electrode (430) comprises a first conductive layer (431), a rare earth metal carbide containing layer (432), and a second conductive layer (433). Those layers and deposition methods for forming those layers are described in more detail elsewhere herein. In an exemplary embodiment, at least one of the first conductive layer (431) and the second conductive layer (433) comprises titanium nitride, and the rare earth metal carbide containing layer (432) comprises cerium carbide.

An effective work function of a gate electrode (430) comprising a rare earth metal carbide containing layer (432) can from at least 4.0 eV to at most 5.6 eV. An effective work function of a gate stack can be shifted by about 10 meV to about 400 meV, or about 30 meV to about 300 meV, or about 50 meV to about 200 meV using rare earth metal carbide containing layer as described herein.

A rare earth metal carbide containing layer (432) can form a continuous film at a thickness of less than <5 nm, <4 nm, <3 nm, <2 nm, <1.5 nm, <1.2 nm, <1.0 nm, or <0.9 nm. The rare earth metal carbide containing layer (432) can be relatively smooth, with relatively low grain boundary formation. In some cases, the rare earth metal carbide containing layer (432) may be at least partially amorphous. In some embodiments, the rare earth metal carbide containing layer (432) can be entirely or substantially entirely amorphous. The RMS roughness of an exemplary rare earth metal carbide containing layer (432) can be <1.0 nm, <0.7 nm, <0.5 nm, <0.4 nm, <0.35 nm, or <0.3 nm, at a thickness of less than 10 nm. In some embodiments, the rare earth metal carbide containing layer (432) may comprise isolated islands, gaps, and/or holes. The rare earth metal carbide containing layer (432) may even entirely consist of a plurality of isolated atoms and/or clusters of atoms.

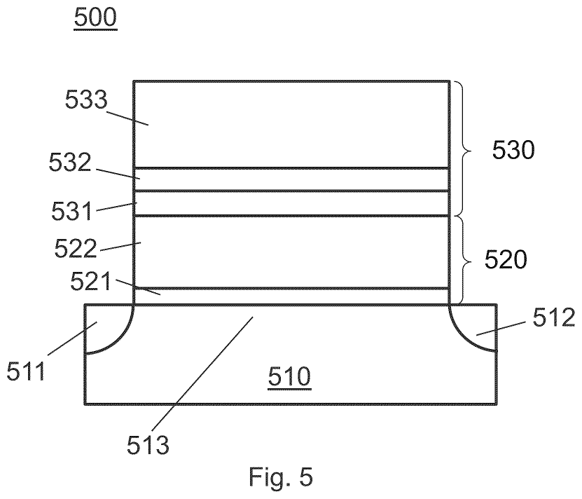

FIG. 5 illustrates another exemplary structure (500) in accordance with examples of the disclosure. The device or structure (500) includes a substrate (510), a gate dielectric (520), and a gate electrode (530). The gate dielectric (520) comprises an interfacial layer (521) and a high-k dielectric layer (522). A suitable interfacial layer includes silicon oxide. The structure further comprises a gate electrode (530) comprising a first conductive layer (531), a rare earth metal carbide containing layer (532), and a second conductive layer (533). In the illustrated example, the substrate (510) includes a source region (511), a drain region (512), and a channel region (513). By applying bias, i.e. a negative or positive voltage, to the gate electrode (530), a conductive channel between the source region (511) and the drain region (512) can be formed in the channel region (513). The nature of the gate dielectric (520) and the gate electrode (530), in particular the nature of the rare earth metal carbide containing layer determines the voltage at which this conductive channel. Although illustrated as a horizontal structure, structures and devices in accordance with examples of the disclosure can include vertical and/or three-dimensional structures and devices, such as FinFET devices, gate-all-around field effect transistors, and stacked device architectures.

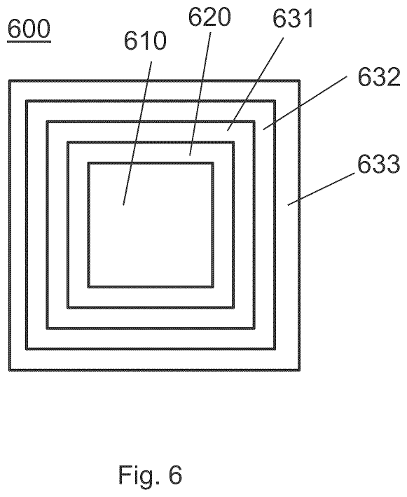

FIG. 6 illustrates another structure (600) in accordance with examples of the disclosure. This structure (600) is suitable for gate all around field effect transistors (GAA FETs) (also referred to as lateral nanowire FETs) devices and the like. In the illustrated example, the structure (600) includes a semiconductor material, i.e. a channel region (610) and a gate dielectric (620) surrounding the channel region (610). The structure (600) further comprises a gate electrode surrounding the gate dielectric (620). The gate electrode comprises a first conductive layer (631), a rare earth metal carbide containing layer (632) as described herein, and a second conductive layer (633). The channel region (620) can include any suitable semiconducting material. For example, the semiconductor material can include Group IV, Group III-V, or Group II-VI semiconductor material. By way of example, the semiconductor material includes silicon, or more specifically monocrystalline silicon.

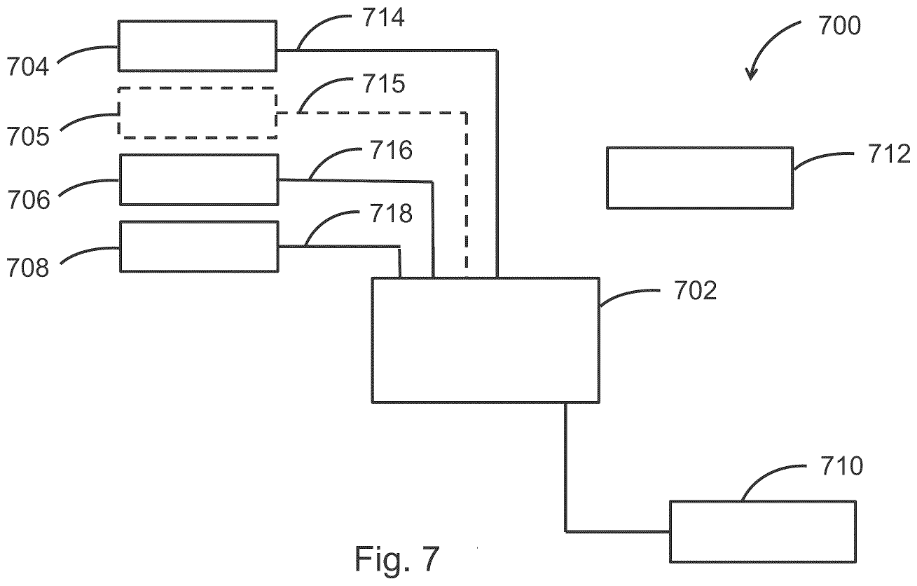

FIG. 7 illustrates a system (700) in accordance with yet additional exemplary embodiments of the disclosure. The system (700) can be used to perform a method as described herein and/or form a structure or device portion as described herein.

In the illustrated example, the system (700) includes one or more reaction chambers (702), a precursor gas source (704), a reactant gas source (706), a purge gas source (708), an exhaust (710), and a controller (712). The reaction chamber (702) can include any suitable reaction chamber, such as an ALD or CVD reaction chamber. Optionally, the system (700) comprises further gas sources such as an optional hydrogen containing gas source (705) and an optional further precursor source (not shown).

The precursor gas source (704) can include a vessel and one or more precursors as described herein—alone or mixed with one or more carrier (e.g., inert) gases. The reactant gas source (706) can include a vessel and one or more reactants as described herein—alone or mixed with one or more carrier gases. The purge gas source (708) can include one or more inert gases such as N₂ or a noble gas, as described herein. The system (700) can include any suitable number of gas sources. The gas sources (704)-(708) can be coupled to reaction chamber (702) via lines (714)-(718), which can each include flow controllers, valves, heaters, and the like. The exhaust (710) can include one or more vacuum pumps.

The controller (712) includes electronic circuitry and software to selectively operate valves, manifolds, heaters, pumps and other components included in the system (700). Such circuitry and components operate to introduce precursors, reactants, and purge gases from the respective sources (704)-(708). The controller (712) can control timing of gas pulse sequences, temperature of the substrate and/or reaction chamber, pressure within the reaction chamber, and various other operations to provide proper operation of the system (700). The controller (712) can include control software to electrically or pneumatically control valves to control flow of precursors, reactants and purge gases into and out of the reaction chamber (702). The controller (712) can include modules such as a software or hardware component, e.g., a FPGA or ASIC, which performs certain tasks. A module can advantageously be configured to reside on the addressable storage medium of the control system and be configured to execute one or more processes.

Other configurations of the system (700) are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber (702). Further, as a schematic representation of a system, many components have been omitted for simplicity of illustration, and such components may include, for example, various valves, manifolds, purifiers, heaters, containers, vents, and/or bypasses.

During operation of the reactor system (700), substrates, such as semiconductor wafers (not illustrated), are transferred from, e.g., a substrate handling system to reaction chamber (702). Once substrate(s) are transferred to the reaction chamber (702), one or more gases from the gas sources (704)-(708), such as precursors, reactants, carrier gases, and/or purge gases, are introduced into reaction chamber (702).

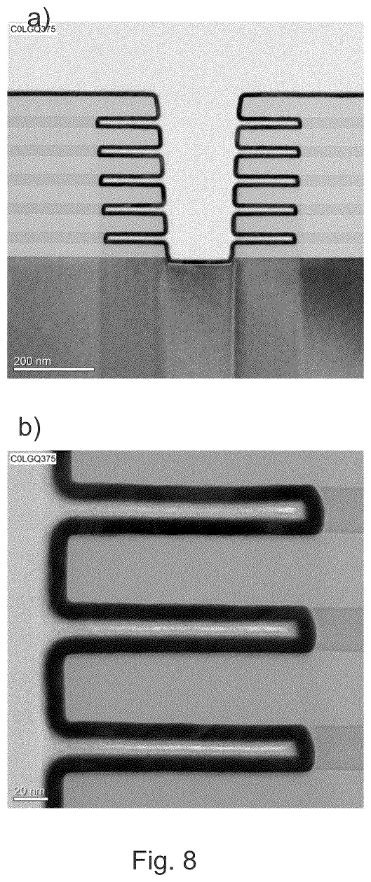

FIG. 8 shows transmission electron micrographs of a high aspect ratio test structure comprising a rare earth metal carbide containing layer deposited by means of an embodiment of a method as disclosed herein. In particular, panel a) provides a zoomed out view of the test structure, and panel b) shows a higher resolution micrograph. The test structure comprises the following stack of conformally deposited layers: HfO₂ as a high k dielectric, 1.5 TiN as a first conductive layer, and 5 nm cerium carbide as a rare earth metal carbide containing layer. As shown in panels a) and b), the methods disclosed herein allow obtaining excellent step coverage. Sample preparation was as follows: TEM-ready samples were prepared using an in-situ focused ion beam (FIB) lift out technique on a FEI Strata 400 Dual Beam FIB/SEM. The samples were capped with sputtered Ir and e-Pt/I-Pt prior to milling. TEM lamella thickness was ˜100 nm. The samples were imaged with a FEI Tecnai TF-20 FEG/TEM operated at 200 kV in bright-field (BF) TEM mode, high-resolution (HR) TEM mode, and high-angle annular dark-field (HAADF) STEM mode. The STEM probe size was 0.2 nm nominal diameter. EDS spectra were acquired in STEM mode using FEI Osiris 4SDD system.

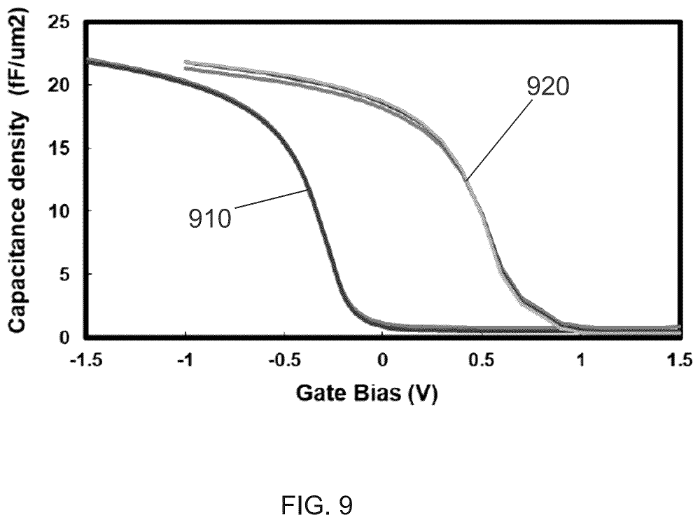

FIG. 9 shows capacitance-voltage (CV) curves for metal-oxide-semiconductor capacitor (MOSCAP) test structures comprising a gate electrode with and without a rare earth metal carbide containing layer. The test structure specifically comprises an Ohmic contact to a p-type substrate, a gate dielectric, and a gate electrode. The left curve (910) shows CV measurements as a function of gate bias when a TiN electrode was used, i.e. an electrode without rare earth metal carbide containing layer. The right curve (920) shows CV measurements as a function of gate bias when an electrode comprising a rare earth metal carbide containing layer was used. In particular, the electrode comprises the following layers: 1.5 nm TiN as a first conductive layer, 3 nm cerium carbide as a rare earth metal carbide containing layer, and 10 nm TiN as a second conductive layer. Cerium Carbide deposition was carried out at 425° C. at a pressure of 1.3 Torr. Ce(iPrCp)₃ was used as a precursor. The precursor pulse time was 6 s, and the intra-cycle purge time was 10 s. Diiodoethane was used as a reactant. A vessel maintained at a temperature of 130° C. was used as a precursor source. Diiodoethane was maintained in a vessel at room temperature. The reactant pulse time was 5 s and the inter-cycle purge time was 10 s. The cerium carbide layer was deposited using 400 pulses. The CV measurements shown in FIG. 9 show that the electrode's effective work function increases by 0.8 eV when a 3 nm cerium carbide layer is incorporated in the gate electrode. The CV curves were carried out at a frequency of at least 1 kHz to at most 100 kHz.

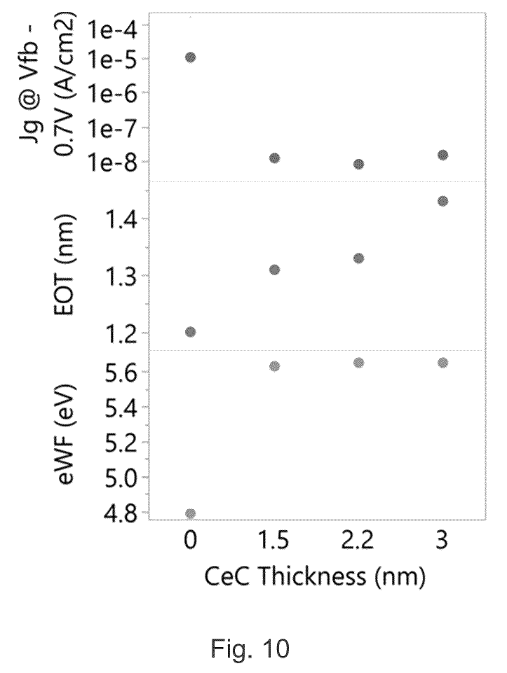

FIG. 10 shows further results of CV voltage measurements on test structures which are identical to the test structure described in the context of FIG. 9, except for the thickness of the cerium carbide layer. In particular, FIG. 10 shows results for cerium carbide layers having a thickness of 1.5 nm, 2.2 nm, and 3 nm. The 1.5 nm thick layer was deposited using 400 cycles, the 2.2 nm thick layer was deposited using 600 cycles, and the 3 nm thick layer was deposited using 800 cycles. The data points shown for 0 nm are reference measurements on structures in which the electrode does not comprise a cerium carbide layer. The measurements indicate that the effective work function can be increased by 0.8 eV even for a cerium carbide layer that has a thickness of only 1.5 nm. The effective work function does not substantially increase any further when the cerium carbide layer thickness is further increased. The measurements additionally indicate that the gate current at the flatband voltage—0.7 volts decreases by 3 orders of magnitude when a cerium carbide layer having a thickness of only 1.5 nm is used. The gate current does not substantially change when a thicker cerium carbide layer is used. The equivalent oxide thickness of the MOSCAP's gate stack increases by only 0.1 nm when a cerium carbide layer of only 1.5 nm is used. The equivalent oxide thickness gradually increases with increasing cerium carbide layer thickness.

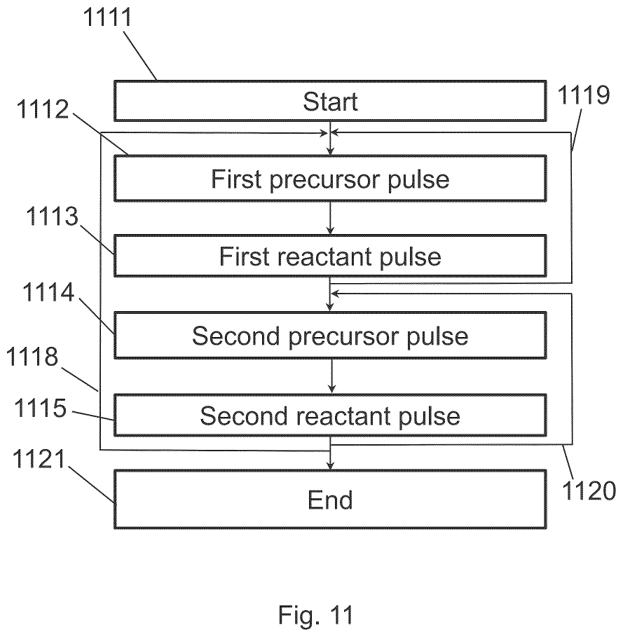

FIG. 11 shows another embodiment of a method as described herein. In particular, FIG. 11 shows a method which can be used to deposit a rare earth metal carbide containing layer, such as, for example, as a step of depositing a rare earth metal carbide containing layer (314) in an embodiment of a method according FIG. 3. The method according to FIG. 11 starts (1111) after a substrate has been provided to a reaction chamber. The reaction chamber can be or can include a reaction chamber of a chemical vapor deposition reactor system configured to perform a cyclical deposition process. Additionally or alternatively, the reaction chamber can be or can include a reaction chamber of an atomic layer deposition reactor system configured to perform a cyclical deposition process. The reaction chamber can be a standalone reaction chamber or be a part of a cluster tool. The method according to FIG. 11 comprises two sub-cycles: a first sub-cycle (1119) and a second sub-cycle (1120). In some embodiments, at least one of the first sub-cycle (1119) and the second sub-cycle (1120) is be repeated one or more times. The first sub-cycle (1119) comprises depositing a rare earth metal carbide containing sub-layer by means of a cyclical deposition process that can be repeated (1119) one or more times. The number of repetitions determine the thickness of this rare earth metal carbide containing sub-layer. The first sub-cycle (1119) comprises a first precursor pulse (1112) in which a rare earth metal precursor is provided to the reaction chamber. Any rare earth metal precursor mentioned herein can be used in the first precursor pulse (1112). The first sub-cycle (1119) further comprises a first reactant pulse (1113) in which a first reactant is provided to the reaction chamber. Any carbon reactant mentioned herein can be provided to the reaction chamber in the first reactant pulse (1113). The second sub-cycle (1120) comprises a second precursor pulse (1114) and a second reactant pulse (1115). In the second precursor pulse (1114), a transition metal precursor is provided to the reaction chamber. Any transition metal precursor mentioned herein can be used in the second precursor pulse (1114). In the second reactant pulse, any nitrogen reactant can be used. Suitable nitrogen reactants include nitrogen-containing gasses such as N₂ and NH₃. Alternatively, a carbon reactant can be used in the second reactant pulse. Suitable carbon reactants include the carbon reactants mentioned elsewhere herein. In some embodiments, at least one of the first sub-cycle (1119) and the second sub-cycle (1120) are repeated one or more times. In some embodiments, the first sub-cycle (1119) is repeated from at least 1 to at most 2, 5, 10, or 20 times. In some embodiments, the second sub-cycle (1120) is repeated from at least 1 to at most 2, 5, 10, or 20 times. The number of repetitions determine the thickness of the sub layers deposited during the first sub-cycle (1119) and the second sub-cycle (1120). The method further comprises a super cycle (1118). The super cycle (1118) comprises the first sub-cycle (1119) and the second sub-cycle (1120). In some embodiments, the super cycle (1118) is repeated one or more times. In some embodiments, the super cycle (1118) is repeated from at least 1 to at most 2, 5, 10, or 20 times. By repeating the super cycle (1118) several times, a layer comprising a plurality of alternating sub layers can be obtained. The super cycle (1118) can be repeated any number of times in order to obtain a desired layer thickness. Optionally, the reaction chamber can be purged after the first precursor pulse (1112). Optionally, the reaction chamber can be purged after the first reactant pulse (1113). Optionally, the reaction chamber can be purged after the second precursor pulse (1114). Optionally, the reaction chamber can be purged after the second reactant pulse (1115). When a layer having a desired thickness has been deposited, the method ends (1121). Once the method has ended, the substrate can, for example, be subjected to additional processes to form a device structure and/or device.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for depositing a rare earth metal carbide containing layer on a substrate, the method comprising the steps of:
providing a substrate within a reaction chamber, the substrate comprising a surface layer;
depositing a rare earth metal carbide containing layer onto the surface layer by means of a cyclical deposition process, the cyclical deposition process comprising one or more cycles, a cycle comprising:
providing a rare earth metal precursor to the reaction chamber in a precursor pulse; and
providing a carbon reactant to the reaction chamber in a reactant pulse,
wherein the rare earth metal precursor comprises a rare earth metal and a substituted or unsubstituted cyclopentadienyl ligand, and
wherein the carbon reactant comprises a halogenated C1 to C6 alkane or alkene.

2. The method according to claim 1, wherein the rare earth metal carbide containing layer comprises a rare earth metal carbide selected from lanthanum carbide, yttrium carbide, erbium carbide, samarium carbide, europium carbide, ytterbium carbide, and cerium carbide.

3. The method according to claim 1, wherein the rare earth metal precursor is selected from a lanthanum precursor, an yttrium precursor, an erbium precursor, a samarium precursor, a europium precursor, an ytterbium precursor, and a cerium precursor.

4. The method according to claim 1, wherein the rare earth metal precursor is selected from a lanthanum precursor, an yttrium precursor, an erbium precursor, a samarium precursor, a europium precursor, and an ytterbium precursor.

5. The method according to claim 1, wherein the alkyl-substituted cyclopentadienyl ligand is selected from EtCp, MeCp, iPrCp, nBuCp, and tBuCp.

6. The method according to claim 5, wherein the rare earth metal precursor comprises Ce(iPrCp)₃.

7. The method according to claim 1, wherein the carbon reactant comprises iodine.

8. The method according to claim 1, wherein the carbon reactant is selected from C₂H₅I, C₂H₄I₂, CH₂I₂, CHI₃, CH₃I.

9. The method according to claim 1, wherein the precursor pulse precedes the reactant pulse.

10. The method according to claim 9, wherein the cyclical deposition process further comprises a first hydrogen pulse, and wherein the first hydrogen pulse comprises providing a first hydrogen containing gas to the reaction chamber.

11. The method according to claim 10, wherein the first hydrogen pulse occurs after the precursor pulse and before the reactant pulse.

12. The method according to claim 11, wherein the cyclical deposition process further comprises a second hydrogen pulse, wherein the second hydrogen pulse comprises providing a second hydrogen containing gas to the reaction chamber, and wherein the second hydrogen pulse occurs after the reactant pulse.

13. The method according to claim 1, wherein the cyclical deposition process comprises a further precursor pulse, wherein the further precursor pulse comprises providing a further precursor to the reaction chamber, and wherein the further precursor and the rare earth metal precursor are different.

14. The method according to claim 13, wherein the further precursor comprises at least one of a rare earth metal and a transition metal.

15. A method for forming an electrode on a substrate, the method comprising the steps of:
providing a substrate within a reaction chamber, the substrate comprising a first conductive layer;
depositing a rare earth metal carbide containing layer onto the surface layer by means of a cyclical deposition process, the cyclical deposition process comprising one or more cycles, a cycle comprising:
providing a rare earth metal precursor to the reaction chamber in a precursor pulse; and
providing a carbon reactant to the reaction chamber in a reactant pulse,
wherein the rare earth metal precursor comprises a rare earth metal and a substituted or unsubstituted cyclopentadienyl ligand, and
wherein the carbon reactant comprises a halogenated C1 to C6 alkane or alkene.

16. The method according to claim 15, wherein the first conductive layer comprises a first transition metal nitride.

17. The method according to claim 15, further comprising a step of depositing a second conductive layer.

18. The method according to claim 15, wherein the first conductive layer comprises a first transition metal carbide.

19. The method according to claim 17, wherein the second conductive layer comprises a second transition metal carbide.

20. A system comprising:
one or more reaction chambers;
a precursor gas source comprising a precursor;
a reactant gas source comprising a reactant;
an exhaust source; and
a controller,
wherein the controller is configured to control gas flow into at least one of the one or more reaction chambers to carry out a method according to claim 1.
